(19) United States
(12) Patent Application Publication
(10) Pub. No.: US 2010/0094535 A1
(43) Pub. Date: Apr. 15, 2010

(54) ELECTRONIC DEVICE AND NAVIGATION DEVICE

(75) Inventor: Huei LIN, Taoyuan (TW)

Correspondence Address: RABIN & Berdo, PC, 1101 14TH STREET, NW, SUITE 500, WASHINGTON, DC, 20005, US

(73) Assignee: Quanta Computer Inc., Tao Yuan Shien (TW)

(21) Appl. No.: 12/407,406

(22) Filed: Mar. 19, 2009

(30) Foreign Application Priority Data
Oct. 13, 2008 (TW) 97218260

(51) Int. Cl. G01C 21/00; H05K 7/00

(52) U.S. Cl. 701/200; 361/679.01

(57) ABSTRACT

An electronic device and a navigation device are provided. The electronic device comprises a display, a frequency modulation (FM) module and a coupling element. The display comprises a display metal frame. The coupling element is electrically connected to the FM module and overlapped with a part of the display metal frame, so as to form a capacitance structure between the coupling element and the display metal frame.

This application claims the benefit of Taiwan application Serial No. 97218260, filed Oct. 13, 2008, the subject matter of which is incorporated herein by reference.

### BACKGROUND OF THE INVENTION

1. Field of the Invention

The invention relates in general to an electronic device, and more particularly to an electronic device which uses the display metal frame as an FM antenna.

2. Description of the Related Art

Frequency modulation (FM) wireless system is widely used in vehicle electronic devices. For example, the navigation device can enable vehicle audio system to broadcast voice navigation by way of FM wireless transmission. The remote controller of a navigation device can also be wirelessly linked via FM frequency band. For example, the navigation device can broadcast voice navigation at a frequency band of 107.8 MHz. Thus, the driver is informed of voice navigation via the audio system in the vehicle.

However, conventional navigation device must have an additional antenna to receive the FM wireless signal. Thus, research engineers do not need to worry about where to accommodate the antenna within such a limited space. Beside, the antenna of a conventional navigation device makes it difficult to further reduce the overall volume of the navigation device. Moreover, the purchase of an additional antenna increases both manufacturing cost and product weight and deteriorates product competitiveness.

### SUMMARY OF THE INVENTION

The invention is directed to an electronic device which uses its existing display metal frame as an FM antenna. Thus, research engineers do not need to worry about where to accommodate the antenna within such a limited space. Also, the overall volume of the product can be further reduced. As there is no need to purchase an additional antenna, manufacturing cost and product weight are reduced, and product competitiveness is increased.

According to a first aspect of the present invention, an electronic device is provided. The electronic device comprises a display, a frequency modulation (FM) module and a coupling element. The display comprises a display metal frame. The coupling element is electrically connected to the FM module and overlapped with a part of the display metal frame, so as to form a capacitance structure between the coupling element and the display metal frame.

According to a second aspect of the present invention, a navigation device is provided. The navigation device comprises a display, a frequency modulation (FM) module and a coupling element. The display comprises a display metal frame. The coupling element is electrically connected to the FM module and overlapped with a part of the display metal frame, so as to form a capacitance structure between the coupling element and the display metal frame.

The invention will become apparent from the following detailed description of the preferred but non-limiting embodiments. The following description is made with reference to the accompanying drawings.

### BRIEF DESCRIPTION OF THE DRAWINGS

FIG. 1 shows an electronic device according to a preferred embodiment of the inventing;

FIG. 2 shows a first external antenna;

FIG. 3 shows a measurement diagram of received signal strength index of the first external antenna;

FIG. 4 shows a second external antenna;

FIG. 5 shows a measurement diagram of received signal strength index of the second external antenna;

FIG. 6 shows a measurement diagram of received signal strength index when the area of the coupling element of the invention is 1/16 times of the area of the display metal frame;

FIG. 7 shows a measurement diagram of received signal strength index when the area of the coupling element of the invention is ⅛ times of the area of the display metal frame;

FIG. 8 shows a measurement result of the decay value of the first external antenna;

FIG. 9 shows a measurement result of the decay value of the second external antenna;

FIG. 10 shows a measurement result of the decay value when the area of the coupling element of the invention is 1/16 times of the area of the display metal frame; and

FIG. 11 s shows a measurement result of the decay value when the area of the coupling element of the invention is ⅛ times of the area of the display metal frame.

### DETAILED DESCRIPTION OF THE INVENTION

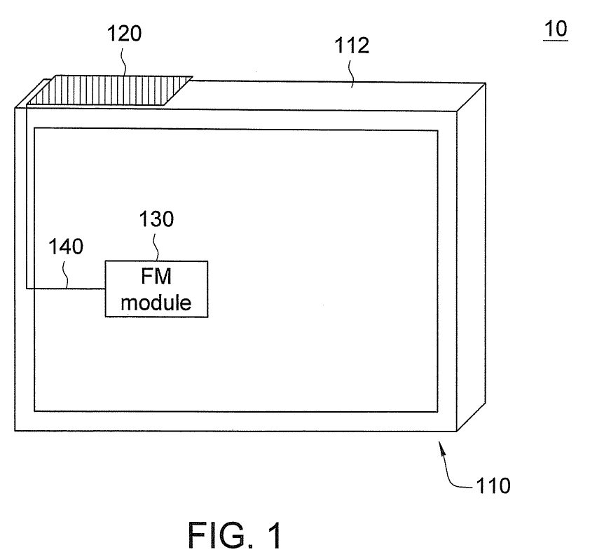

Referring to FIG. 1, an electronic device according to a preferred embodiment of the inventing is shown. The electronic device 10, such as a navigation device, and the electronic device 10 comprises a display 110, a coupling element 120, a frequency modulation (FM) module 130 and a transmission line 140. The display 110 comprises a display metal frame 112. The transmission line 140, such as a single-core cable, electrically connects the FM module 130 to the coupling element 120. The coupling element 120 is a flexible printing circuit (FPC) for example. The coupling element 120 is electrically connected to the FM module 130 via the transmission line 140 and overlapped with a part of the display metal frame 112, so as to form a capacitance structure between the coupling element 120 and the display metal frame 112.

The display metal frame 112 is normally grounded in order to avoid electrostatic discharge (ESD) and suppress display noise. Thus, the display metal frame 112 is normally not used as an FM antenna in conventional methods. As the display 110 is the main source of noise, the display metal frame 112 carries certain amount of noise energy. The operation of the FM module 130 will be severely affected if the display metal frame 112 is directly connected to the FM module 130.

To overcome the above problems, a capacitance structure is formed between the coupling element 120 and the display metal frame 112 to isolate the direct current component and the radio frequency energy with a non-operating frequency band. Thus, the display metal frame 112 with grounding function can be safely used as an FM antenna of the electronic device 10. Besides, when the display metal frame 112 is used as an FM antenna of the electronic device 10, as the display metal frame 112 is grounded, the entire grounding metal portions of the electronic device 10 will become a part of the FM antenna, hence largely increasing the overall wireless efficiency. Furthermore, as the display 110 has the largest area among all elements of the electronic device 10, the electronic device 10 will have a largest radar cross-sectional area if the display metal frame 112 is used as an FM antenna.

As all the grounding portions of the electronic device 10 have become the FM antenna, the noise electric potential of the electronic device 10 equals the interference electric potential coupled to the antenna radiator. Thus, the two electric potentials are exactly the same and there will be no electric potential difference or noise current, such that the problem of electromagnetic compatibility of radio frequency is resolved.

According to the above disclosure, regardless the coupling element 120 is disposed on an outer surface of the display metal frame 112 as is indicated in FIG. 1 or disposed on an inner surface of the display metal frame 112, the effect is the same. To allow the wireless signal of 88 Mhz˜108 MHz FM frequency band to pass through the capacitance structure formed between the coupling element 120 and the display metal frame 112, the area of the coupling element 120 is preferably ⅛˜ 1/16 times of the area of the area of the display metal frame 112. Moreover, as the FM antenna is not a resonator structure, the FM antenna can effectively receive/transmit wireless signals as long as the peripheral length of the display metal frame 112 is larger than 80 mm.

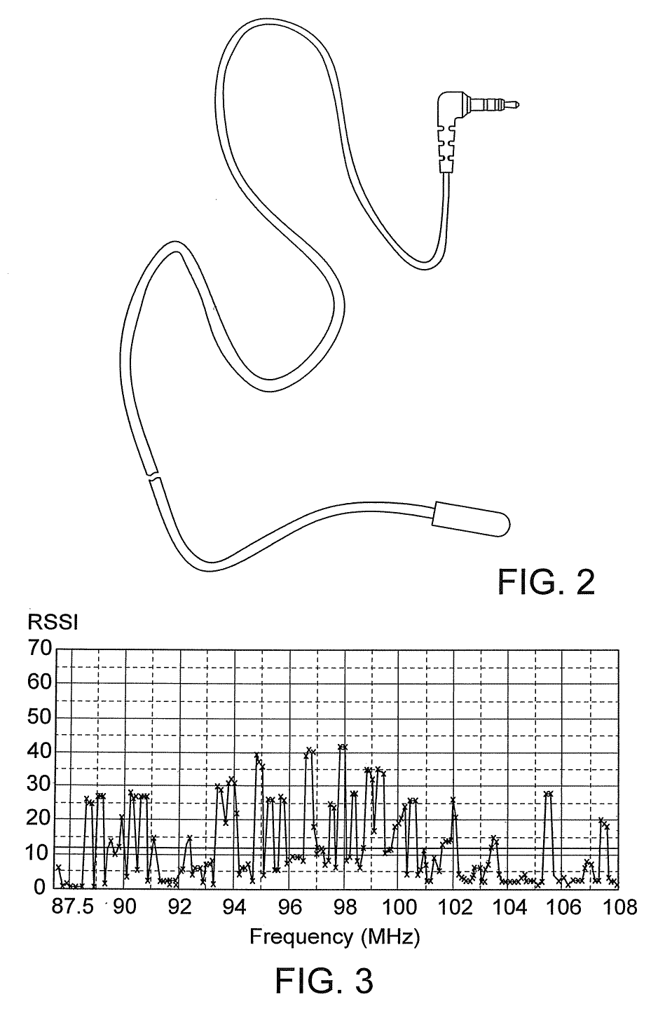

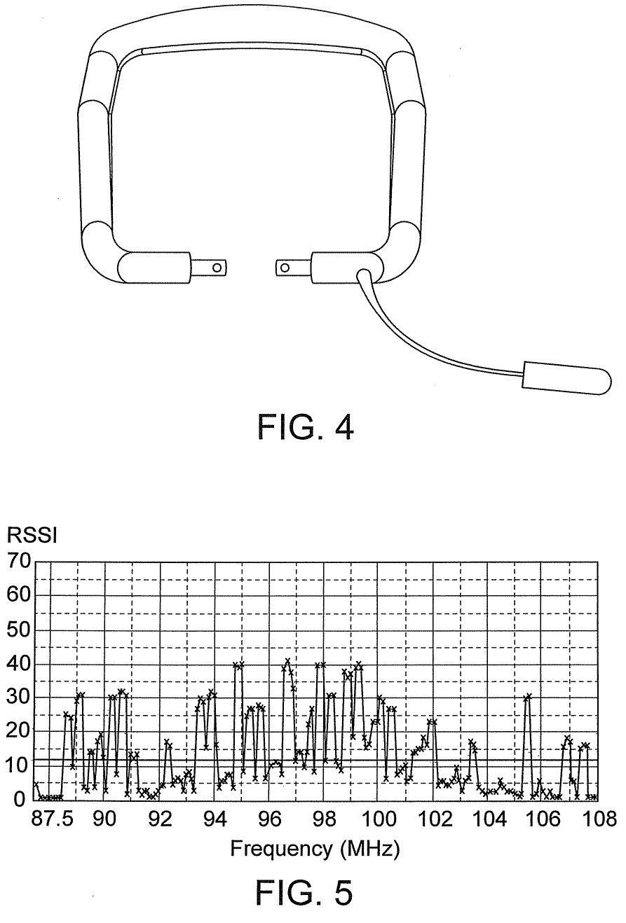

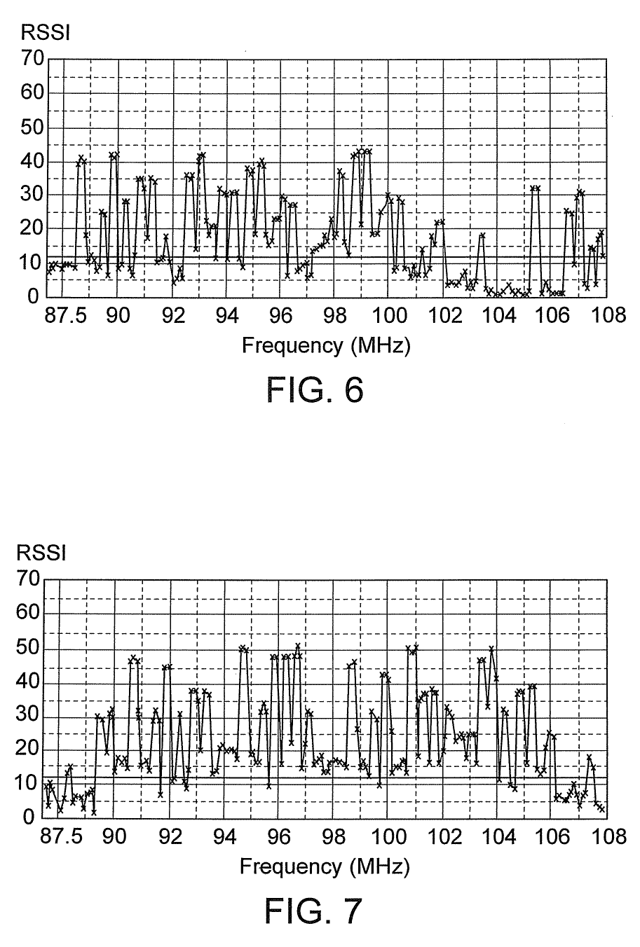

Referring to FIG. 2˜FIG. 7. FIG. 2 shows a first external antenna. FIG. 3 shows a measurement diagram of received signal strength index of the first external antenna. FIG. 4 shows a second external antenna. FIG. 5 shows a measurement diagram of received signal strength index of the second external antenna. FIG. 6 shows a measurement diagram of received signal strength index when the area of the coupling element of the invention is 1/16 times of the area of the display metal frame. FIG. 7 shows a measurement diagram of received signal strength index when the area of the coupling element of the invention is ⅛ times of the area of the display metal frame. As is indicated in FIG. 2˜FIG. 7, no matter the area of the coupling element of the invention is ⅛ or 1/16 times of the area of the display metal frame, the received signal strength index (RSSI) is still superior to the external antenna of FIG. 2 and FIG. 4.

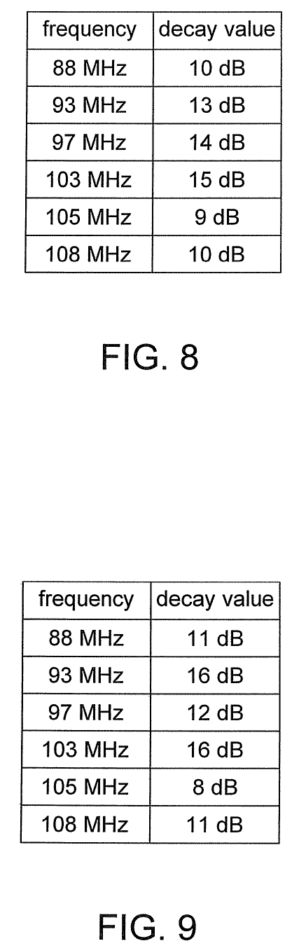

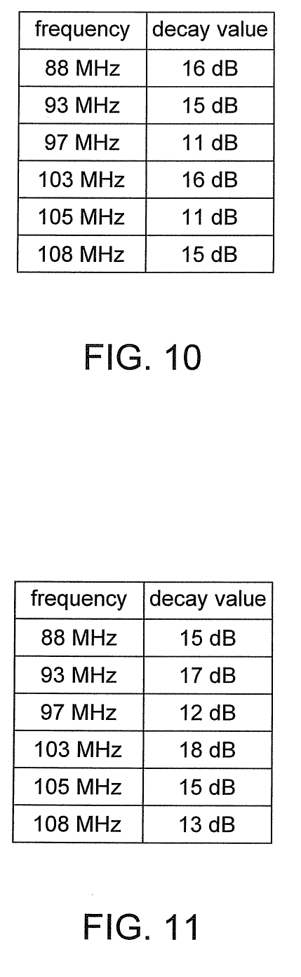

Referring to FIG. 8˜FIG. 11. FIG. 8 shows a measurement result of the decay value of the first external antenna. FIG. 9 shows a measurement result of the decay value of the second external antenna. FIG. 10 shows a measurement result of the decay value when the area of the coupling element of the invention is 1/16 times of the area of the display metal frame. FIG. 11 shows a measurement result of the decay value when the area of the coupling element of the invention is ⅛ times of the area of the display metal frame. The larger the decay value of FIG. 8˜FIG. 11, the better the sensitivity. As is indicated in FIG. 8˜FIG. 11, no matter the area of the coupling element of the invention is ⅛ or 1/16 times of the area of the display metal frame, the sensitivity is still superior to the external antenna of FIG. 2 and FIG. 4.

The electronic device and the navigation device disclosed in the above embodiments of the invention at least comprise the following advantages:

1. Research engineers do not need to worry about where to accommodate the antenna within such a limited space.

2. The overall volume of the product can be further reduced.

3. Manufacturing cost and product weight are reduced and product competitiveness is increased.

4. All the grounding metal portions of the electronic device or the navigation device become a part of the FM antenna, largely increasing entire wireless efficiency.

5. The radar cross-sectional area is the largest.

6. The electromagnetic compatibility of radio frequency is largely increased.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic device, comprising:
a display, comprising:
a display metal frame;
a frequency modulation (FM) module; and
a coupling element electrically connected to the FM module and overlapped with a part of the display metal frame, so as to form a capacitance structure between the coupling element and the display metal frame.

2. The electronic device according to claim 1, wherein the area of the coupling element is ⅛˜ 1/16 times of the area of the display metal frame.

3. The electronic device according to claim 1, wherein the coupling element is a flexible printing circuit (FPC).

4. The electronic device according to claim 1, wherein the area of the coupling element exactly allows the wireless signal of the FM frequency band to pass through the capacitance structure.

5. The electronic device according to claim 1, wherein the coupling element is a flexible printing circuit (FPC).

6. The electronic device according to claim 1, wherein the coupling element is disposed on an outer surface of the display metal frame.

7. The electronic device according to claim 1, wherein the coupling element is disposed on an inner surface of the display metal frame.

8. The electronic device according to claim 1, further comprising a transmission line.

9. The electronic device according to claim 8, wherein the transmission line is a single-core cable.

10. The electronic device according to claim 1, wherein the peripheral length of the display metal frame is larger than 80 mm.

11. A navigation device, comprising:
a display, comprising:
a display metal frame;
a frequency modulation (FM) module; and
a coupling element electrically connected to the FM module and overlapped with a part of the display metal frame, so as to form a capacitance structure between the coupling element and the display metal frame.

12. The navigation device according to claim 11, wherein the area of the coupling element is ⅛˜ 1/16 times of the area of the display metal frame.

13. The navigation device according to claim 11, wherein the coupling element is a flexible printing circuit (FPC).

14. The navigation device according to claim 11, wherein the area of the coupling element exactly allows the wireless signal of the FM frequency band to pass through the capacitance structure.

15. The navigation device according to claim 11, wherein the coupling element is a flexible printing circuit (FPC).

16. The navigation device according to claim 11, wherein the coupling element is disposed on an outer surface of the display metal frame.

17. The navigation device according to claim 11, wherein the coupling element is disposed on an inner surface of the display metal frame.

18. The navigation device according to claim 11, further comprising a transmission line.

19. The navigation device according to claim 18, wherein the transmission line is a single-core cable.

20. The navigation device according to claim 11, wherein the peripheral length of the display metal frame is larger than 80 mm.
